(19) United States
(12) Patent Application Publication
(10) Pub. No.: US 2005/0207280 A1
(43) Pub. Date: Sep. 22, 2005

(54) BIT CLOCK WITH EMBEDDED WORD CLOCK BOUNDARY

(76) Inventors: Michael L. Fowler, Saco, ME (US); James B. Boomer, Falmouth, ME (US); Nathan J. Charland, Saco,, ME (US)

Correspondence Address: CESARI AND MCKENNA, LLP, 88 BLACK FALCON AVENUE, BOSTON, MA, 02210, US

(21) Appl. No.: 10/802,436

(22) Filed: Mar. 16, 2004

(51) Int. Cl. G04B 47/00; H03M 13/00; G06F 11/00

(52) U.S. Cl. 368/10; 341/100; 341/101; 375/354; 714/798

(57) ABSTRACT

A bi-directional serializer/deserializer is disclosed using a single bi-directional data line and a single bi-directional clock line. Gated buffers are controlled to operate either sending or receiving data, and a phase locked loop provides a clock to shift data out from a shift register. A reference clock is supplied to the PLL and the PLL generates a synchronous bit clock. The bit clock is sent over the clock line in parallel with the serial data bits, and the PLL bit clock is synchronized to the data bits. Two data boundary bits are inserted between the word data bits, the boundary data bits are arranged with a logic level transition between the two data boundary bits. Also, at the boundary of the words during the sending of the two boundary data bits, the synchronous bit clock is arranged to have no logic level transition. The receiving system will use the bit clock to serial load the received word and boundary data bits into a shift register. A word boundary is detected by sensing a data bit transition while there is no bit clock.

### CROSS REFERENCE TO RELATED APPLICATIONS

The present invention is related to the co-filed application entitled, “ARCHITECTURE FOR BIDIRECTIONAL SERIALIZERS AND DESERIALIZERS,” Ser. No. 10/802,372, filed on Mar. 16, 2004, and to an application entitled, SENDING AND/OR RECEIVING SERIAL DATA WITH BIT TIMING AND PARALLEL DATA CONVERSION, Ser. No. 10/824,747, filed on Apr. 15, 2004. Both of these applications are owned by the same entity, and both are incorporated herein by reference.

### BACKGROUND OF THE INVENTION

1. Field of the Invention

The present invention relates to data transmission, and more particularly to serializing and sending, bit by bit, data where the data word boundary is determined in order to receive and deserialize the data.

2. Background Information

FIG. 1 illustrates a known serializer in a block schematic form. A parallel data word 10 is loaded into a buffer register 12 with a word clock 14. The word clock 14 is also fed to a phase locked loop (PLL) 16. The PLL generates a bit clock 18 that loads the shift register 20 and subsequently shifts out the data in the shift register 20 serially bit by bit through a cable or transmission line driver 22. The bit clock 18 that shifts the data out bit by bit stays synchronized to the bit positions within the word by the PLL. Along with the serial bits from driver, 22 a word clock 24 is output via driver 26. The receiver will be able to distinguish the beginning and ending of the serial data stream by referencing the bit stream via the word clock.

FIG. 2 shows a receiver circuit that deserializes the bits to form words. The serial data 30 is input to a shift register 32. The word clock 34 is input to a PLL 36 that generates a bit clock 38 that is synchronized to the bit location in a word by the PLL. With this synchronization, the bit clock 38 properly loads the bit stream into the shift register 32. When the word has been received by the shift register 32 (as determined from the word clock), the PLL outputs a clock 40 that loads the parallel data in the shift register 32 into a buffer register 42. The word data 44 is in parallel form ready for use in the receiving system.

FIG. 3 shows a complete bidirectional system using the serializers as in FIG. 1 and deserializers as in FIG. 2. Note that there are 8 data lines and a single clock into each serializer and out from each deserializer. The data and clock lines between the serializer and the deserializer are typically differential signals.

The serializer/deserializers of FIG. 3 each contain a PLL that are common in such devices. PLL's consume significant power, are complex, require long locking times, and occupy considerable chip real estate. It would be advantageous to dispense with PLL's.

FIG. 4 is a timing diagram showing a generic timing chart that illustrates the serial sending of a framed ten bit word. A word clock 60 is fed to a PLL that generates a synchronous bit clock 62. The word clock 60 must occur often enough for the PLL to remain locked. The data bits are loaded into a shift register using a word clock edge. Then, the data bits in the shift register are shifted out serially by the bit clock 62. In FIG. 4, an eight bit word is shifted out on the rising edge of the bit clock 62.

A similar operation applies to the receiving of the serial data. In this case, the word clock is received and applied to a PLL that generates a synchronous (to the word clock) bit clock that is used to load the data bits into a receiving shift register. Data bits must be stable when the clocks cause the data bits to be sent and to be received. Time delays are designed into such systems to accomplish this, as known in the art. In the case shown, the data bits is sent out synchronously where the lowest order bit of the next word is sent out directly after the most significant bit of the prior word. In other instances, the data may be sent out asynchronously, typically using start and stop bits that frame the data bits. In both the synchronous and asynchronous cases, system means must be employed, as are well known in the art, to prepare the sender and the receiver to properly send and receive the data. Also, systems are arranged to send data then, after sending, receive data; while other systems can send and receive simultaneously. The former is referred to as half duplex and the latter as duplex. Again, system designers understand the limitations and requirements of such systems to properly send and receive data.

It is axiomatic that the receiving system must be able to distinguish data word boundaries from a stream of serial bits, as discussed above.

FIGS. 1 and 2 contain a buffer register that holds the word to be sent or the word just received. The buffer allows nearly the entire time for a word to be sent or received before the next word is loaded. The logic and the timing to accomplish these tasks are well known. However, the buffer registers are not required, and if not used, then the word to be sent and the word received must be processed during a bit time. Again, such designs are well known in the art.

In general, transferring serial data offers an advantage over parallel transferring since fewer signals and wires are used. Additionally, fewer signals translate into fewer circuits, fewer signal edges, less currents and, thus, less noise and power dissipation.

### SUMMARY OF THE INVENTION

The present invention provides a method and apparatus for determining data word boundaries from a stream of data bits. One or two boundary data bits are typically located between the data bits of each word. However, the boundary bit or bits may be located within the word data bits or before the word data bits.

When two boundary bits are used, they are arranged so that a logic level transition occurs between the two boundary data bits. A bit clock is sent in parallel and synchronized with serialized data bits, including the boundary data bits. However, the bit clock is arranged to have no logic level transition during word boundaries. The receiving system detects a word boundary logically by sensing a data bit transition when the bit clock has no logic level transition.

When one boundary bit is used, in a preferred embodiment, the boundary data bit exhibits a double frequency, and, if the bit clock is maintained at a constant logic level during the double frequency, a word boundary is detected.

In preferred embodiments, a REF clock is used to lock the PLL's and a WORD clock latches data into buffer registers. The data lines are bi-directional as is the bit clock line. In preferred embodiments, there is an overall master or controller that handles the data and clock direction reversals so that information is not lost. In other preferred embodiments, the synchronization between the sender and the receiver, to turn around the data/clock signal directions, can be handled by control/status line or lines between the two. Protocols may be developed by those skilled in the art to ensure that there is proper control of the communications between the sending and receiving systems. For example, if busy were not asserted, the system wanting control would assert busy. At some random time, the system would dis-assert busy in case the prospective receiver asserted busy at the identical time. If the busy signal remained asserted, that side would delay taking control until the other side finished and dis-asserted busy. If the busy signal went disasserted, that side would re-assert the busy and send its message. Information being transferred would typically have error check system, so that if there was contention remaining on the communication, improper information would be detected and the transfer re-tried at some later time. Such techniques and systems are well known in the art.

In other preferred embodiments, the data line is bi-directional but there are two unidirectional clock lines. In yet other preferred embodiments, both the data lines and the clock lines are unidirectional. This embodiment is needed when high speed data is sent over longer distances.

In yet another preferred embodiment, the boundary bits may be used to determine the number of bits in the data word. However, additional bits may be present in the “data” stream before the beginning of the data word. These bits are referred to as filler bits. These filler bits may be present in the following discussions although not specifically mentioned.

It will be appreciated by those skilled in the art that although the following Detailed Description will proceed with reference being made to illustrative embodiments, the drawings, and methods of use, the present invention is not intended to be limited to these embodiments and methods of use. Rather, the present invention is of broad scope and is intended to be defined as only set forth in the accompanying claims.

### BRIEF DESCRIPTION OF THE DRAWINGS

The invention description below refers to the accompanying drawings, of which:

FIGS. 1 and 2 are block diagram schematics of a prior art serializer and deserializer;

FIG. 3 is a system block diagram of a prior art duplex system;

FIG. 4 is a representative prior art timing chart;

FIG. 5 is a block diagram schematic of an embodiment of the present invention;

FIG. 6 is a mode table;

FIGS. 7 and 8A are data bit timing charts;

FIG. 8B is a schematic of a logic circuit that detects word boundaries in the bit clock;

FIG. 9 illustrates a bus hold circuit;

FIG. 10 is a schematic of a gated transmission line termination;

FIG. 11 shows a wired or status bit;

FIGS. 12, 13, 14 and 15 illustrate different operation applications of embodiments of the present invention;

FIGS. 16 and 17 illustrate simplified bi-directional applications of embodiments of the present invention;

FIGS. 18, 19A and 19B are timing diagrams showing various placements of the word boundaries;

FIG. 20A is another timing diagram; and

FIG. 20B is a circuit block diagram that implements the embodiment of FIG. 20A.

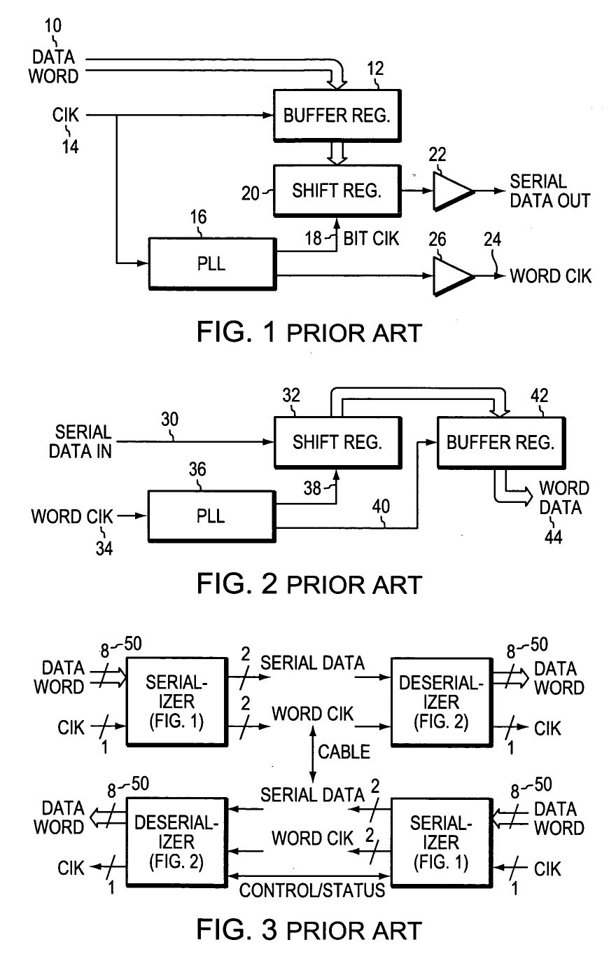

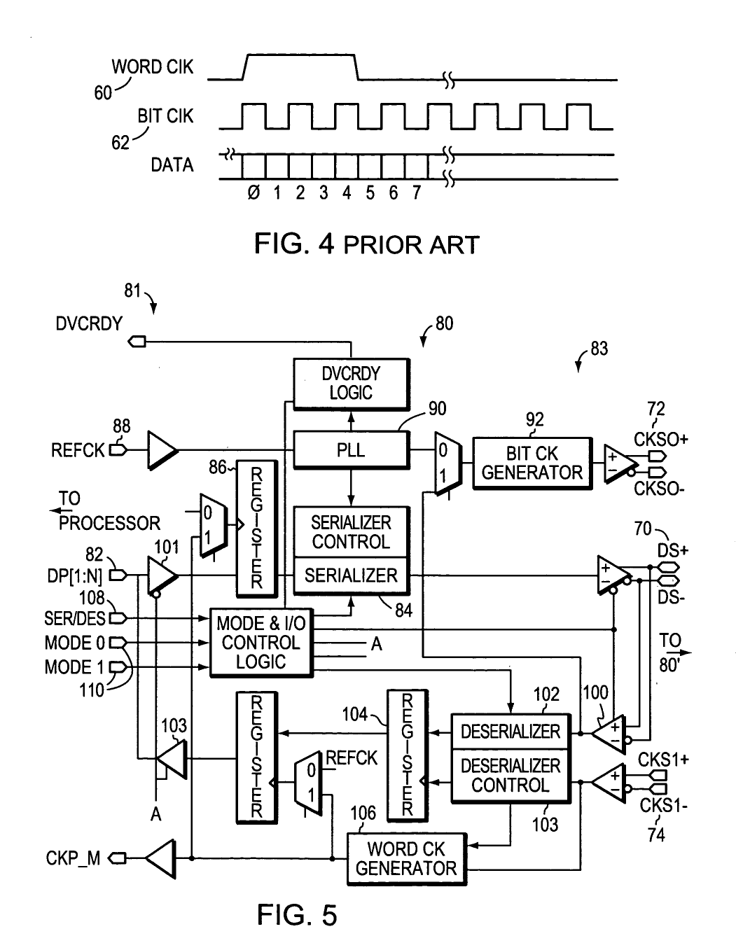

### DETAILED DESCRIPTION OF AN ILLUSTRATIVE EMBODIMENT

FIG. 5 is a block diagram that indicates the operation at a high, functional level showing a serializer/deserializer 80. The left side 81 of FIG. 5 shows electrical contact points arranged to be connected to a processor or computer bus system while the rights side 83 of FIG. 5 is arranged to connect to a transmission cable, or the like, that connects to corresponding pins on serializer/desrializer 80′ that is similar to the serializer/deserializer 80. The data lines (DS+, DS−) 70, the clock out lines (CKSO+, CKSO−) 72 and the clock in lines (CKS1+, CKS1−) 74 are typically differential pairs as shown. Line drivers and receivers for differential pairs are well known in the art. Moreover, in particular applications, the clock in and clock out lines may be joined together so that only a single data pair and a single clock pair are output to connect to another serializer/deserializer 80.′ These differential pairs will be referred to as CKSO, CKS1, and DS unless a specific reference is clearer referring to the individual signals.

When device 80 is sending out data, parallel data 82 from a processor bus is loaded into a register 86 that holds the data for loading into a shift register serializer 84. REFCLK 88 drives and synchronizes the PLL 90 that generates a synchronous (to the REFCLK) bit clock 92 that is sent out via 72. A receiver system 80′ is arranged to accept the bit clock 72 and clock in the serial data bits as they arrive on the data lines 70. A signal from the PLL also drives the serializer control and serializer 84 causing the bits to be shifted out 70 synchronized to the bit clock 72. An edge of bit clock 72 occurs while the data bits 70 are stable allowing the receiver to reliably clock in the received data 70.

When the serializer/deserializer 80 is arranged to receive data via the differential receiver 100. The received clock signals 74 are used to clock in the data into the deserilizer 102. When a full word is received the deserializer control 103 loads the word into the register 104. A word clock is generated 106 informing the processor system, connected to 81, of the receipt of a complete word.

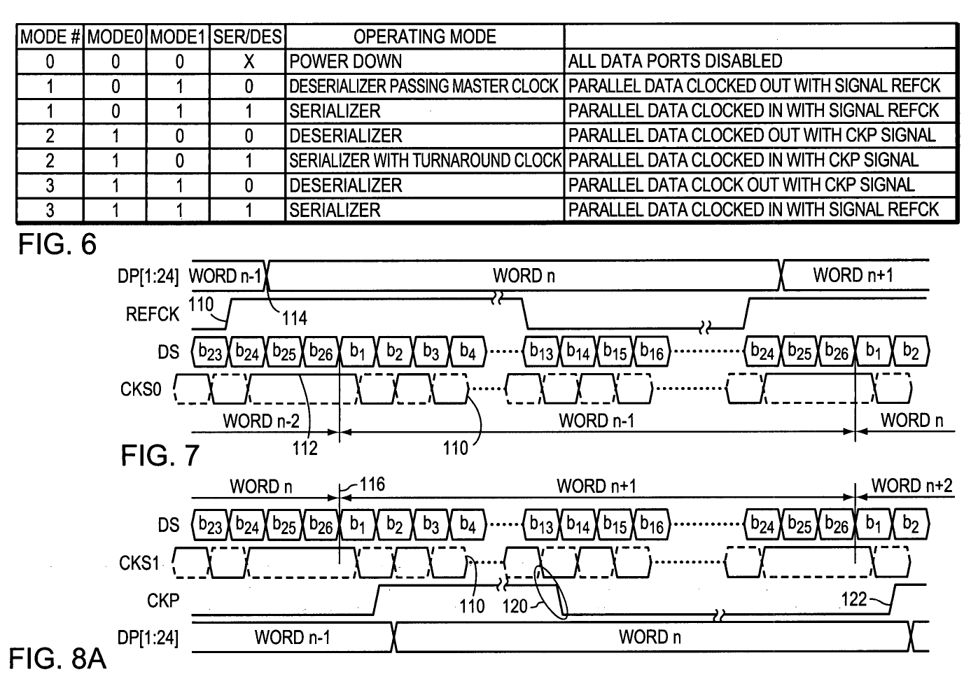

The SER/DES signal programs the device 80 to be a sender when high or a receiver when low. These signals may be wired high or low or controlled by the processor. The MODE0 and MODE1 110 inputs, along with the SER/DES signal, determine the operating characteristics of the device 80, that are shown in FIG. 6. Although the following mode control is described, other approaches to controlling the serializer/deserializer can be used. For example, in simplest form, control is maintained by the SER/DES signal alone, or a separate control port could be used.

FIG. 5 shows a serializer that may be implemented as a shift register, or by multiple shift registers, or by multiple shift registers outputting data via multiplexer. A serializer may also be one or more multiplexers that select and output each bit of a word from a holding buffer register. Correspondingly, a deserializer may be formed by a shift register and/or multiple multiplexers and a holding register.

The following description includes FIG. 5 with respect to each of the logic conditions shown in FIG. 6 and the timing of FIG. 7.

FIG. 6 mode # 0 is a power down condition where the device is disabled.

In mode #1 or # 3 where SER/DES signal is high, the device operates as a serializer. Parallel data 82 is latched into register 86 on the rising edge of REFCK, and clocked out serially 70 via 84. CKSO 72 is synchronously generated with the serial data signals. In one embodiment, WORD n−1 of twenty four data bits, see FIG. 7—b1-b24, are first loaded on the rising edge of REFCK into the register 86. A word boundary is formed in the bit clock CKSO 112 (FIG.7). Bits b25 and b26 are added between the prior word sent (WORD n−2) and WORD n−1. Then, four bit clocks after the rising edge of REFCK, b1 of WORD n−1 is synchronously clocked out immediately after the end of the two bit word boundary 112. Data bits b25 and b26 fill in the space between the two words being sent.

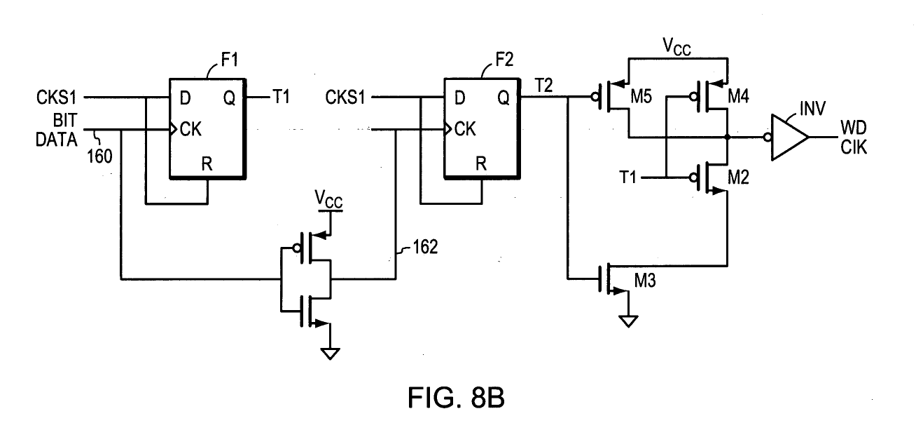

In mode #3, when SER/DES signal is low, the device operates as a deserializer, the timing chart FIG. 8 applies. Data is received at 70 on FIG. 5, synchronously with the bit clock CKS1. The received data bits are loaded into the deserializer and a word clock CKP generated. The falling edge of the bit clock CKS1 will initiate the falling edge of the CKP 120. The rising edge 122 of CKP will occur about twelve bit times later (one half of a twenty-four bit word). Parallel data will appear about 2 bit clock times after the rising edge of CKP. In parallel, an optional REFCK can be provided as a reference the PLL. The PLL will generate a bit clock transmitted out as CKSO, if needed.

In mode #2 with SER/DES signal low the device is a deserializer. Data (DS) is received synchronously with the received bit clock CKS1. The data is deserialized, the bit b25 and b26 in the word boundary are stripped and the resulting parallel word may be retrieved by the processor on data lines DP 82 of FIG. 5. The bit clock CKS1 will also generate the CKP word clock, and CKSO is held low.

In mode #2 when SER/DES signal is high, the device deserializes received data synchronously with the received bit clock CKS1. The data in the word boundary data, b25 and b26, is stripped by the deserializer control 103 (FIG. 5) from the twenty-four word data bits. The word data is then made available on the parallel port 82 (FIG. 5) for the processor. The word clock CKP is also available to the processor.

In mode #1 with SER/DES signal low, the device acts as a bidirectional deserializer. In this operation REFCK, via the PLL, sends out the clock CKSO to be used to clock the serial data by the upstream sending device. Deserialized data is synchronously received on the DS and CLS1 ports. The data in the word boundary is stripped, as before, and the data word is synchronously, with the REFCK, sent out on the parallel port DP for the processor to accept.

Operation of a system of FIG. 5 with bi-directional data and clock lines will be useful at lower system speeds. When higher speed are necessary, the data and the clock lines may be cabled independently so that there are two data lines each transferring unidirectional data in opposite directions and separate unidirectional clock lines with clocks traveling in opposite directions. The serializer/deserializers 90 and 90′ may also be operated with two clock lines, but a single bi-directional data line, or a single bi-directional clock line and two unidirectional data lines.

The input buffers 101, FIG. 5, are low voltage CMOS circuits with a nominal threshold of about ½ the powering voltage, VDD, that are operational only when the device 80 is a serializer. They are held off to conserve power when the device is a deserializer.

The output buffers 103 are three state circuits that will source/sink 2 mA's at 1.8V and are active only when the device 80 is a deserializer. They are held in the high-Z state when the device 80 is a serializer.

CMOS devices with low, 2 mA, drive currents were used throughout embodiments of these circuits. However, TTL or LV_TTL or even differential signaling could be used and the drive current could be of any logic type, from very low currents (sub-mA's) to very high currents (100's of mA's).

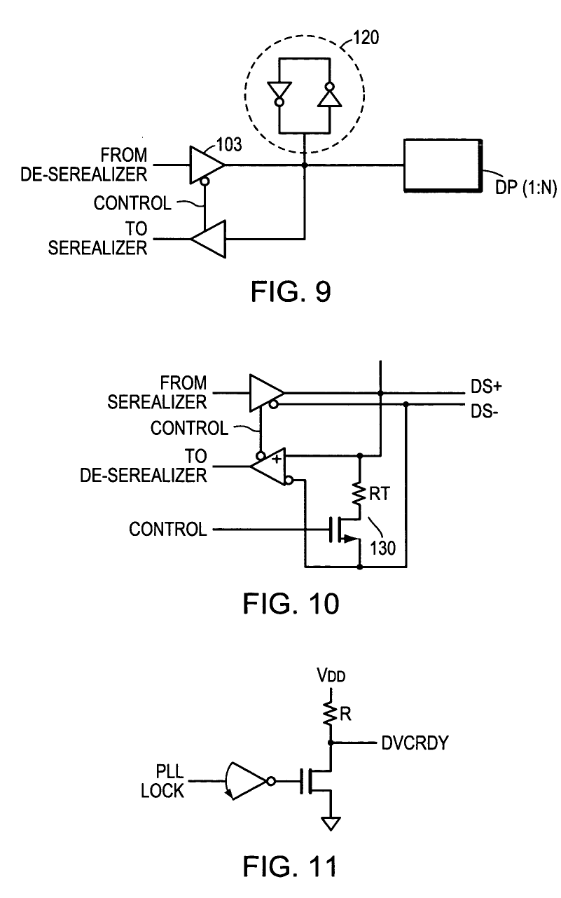

FIG. 9 shows a gate hold circuit, known in the art, that maintains the last state of the DP lines when the driver 103 goes high-Z. There is a gated differential line termination 130 shown in FIG. 10. When the device 80 is a deserializer, received data on the DS lines is terminated with a series resistor and one CMOS transistor. The value of the resistor RT and the on resistance value of the CMOS transistor are selected to match the transmission line characteristic impedance.

Referring back to FIG. 5, there is a DVCRDY signal available to the processor. When the PLL is locked this signal becomes true. FIG. 11 shows this signal available as a wired OR. Since a PLL may take some time to become locked, this signal can be used by the processor to ensure that the device 80 is ready.

Referring back to FIGS. 7 and 8A, there is shown a bit clock CKSO and CKS1, respectively. In each case, at the sending word boundary 114 of FIG. 7, CKSO remains high, and data bits b25 and b26 are sent over the data lines. In FIG. 8 at the word boundary 116 the CKS1 is high and data bits b25 and b26 are received. Please note that in this discussion the CKSO and CKS1 go high during the word boundaries, but a system could be implemented with them going low, as would be known to those in this art. When not at a word boundary, the clocks in both FIGS. 7 and 8A provide an edge during each data bit time. The data bits are sent or retrieved during both the rising and the falling edges of the bits clocks. The system that is sending or receiving data will detect the word boundary by recognizing that there was no clock pulse between two data bits. In FIGS. 7 and 8 the missing clock pulse means that a clock edge is found at the end of b24 (to load b24), but there is no clock edge for b25 and none for b26. The data bits at the word boundary are arranged so that there will always be an edge between bits b25 and b26, so if no clock pulse is detected between any data transition of any two bits, those bits must be the word boundary bits, b25 and b26. The logic implementation to perform this detection is well known in the art. One design, where say the clock stayed high during the word boundary, would have a flop that toggles on each clock falling edge. In one preferred embodiment, the first boundary bit will always be arranged to have a transition edge with respect to the previous data bit, and then there will be another logic transition between the two boundary bits. So, if the previous data bit is a logic 1, the succeeding boundary bits will be logic 0,1; and if the previous data bit is a 0, the boundary bits will be 1,0.

When a system is sending data, the sender knows where the word boundaries are, so deleting a clock pulse is straight forward, but not so when receiving serial data. FIG. 8B shows one logic circuit that can be used to detect a missing clock pulse during a data bit transition (the sender always requiring a transition of the data stream during the word boundary). F1 and F2 are D type flip flops with the received bit data 160 fed to the clock is input of F1 and the bit data inverted 162 fed to the clock of F2. The D inputs and the resets of both flops are connected to the received bit clock CKS1. CMOS transistors M2, M3, M4, and M5 are arranged as an AND with an inverter INV to form a NAND circuit with inputs t1 and t2 from the flop outputs, and an output is the word clock WDCLK. In operation, when CKS1 is low, both flops are reset and t1 and t2 are low. So the WDCLK is low. When CKS1 is high and data transitions occur either t1 or t2 will go high but not both. On the next low going CKS1 edge, both flop outputs will again go low. When CKS1 is high for two consecutive bit times and data toggles high and low during this period, both t1 and t2 will go high and, via the NAND, WDCLK will go high. On the next falling edge of CKS1, WDCLK will go low.

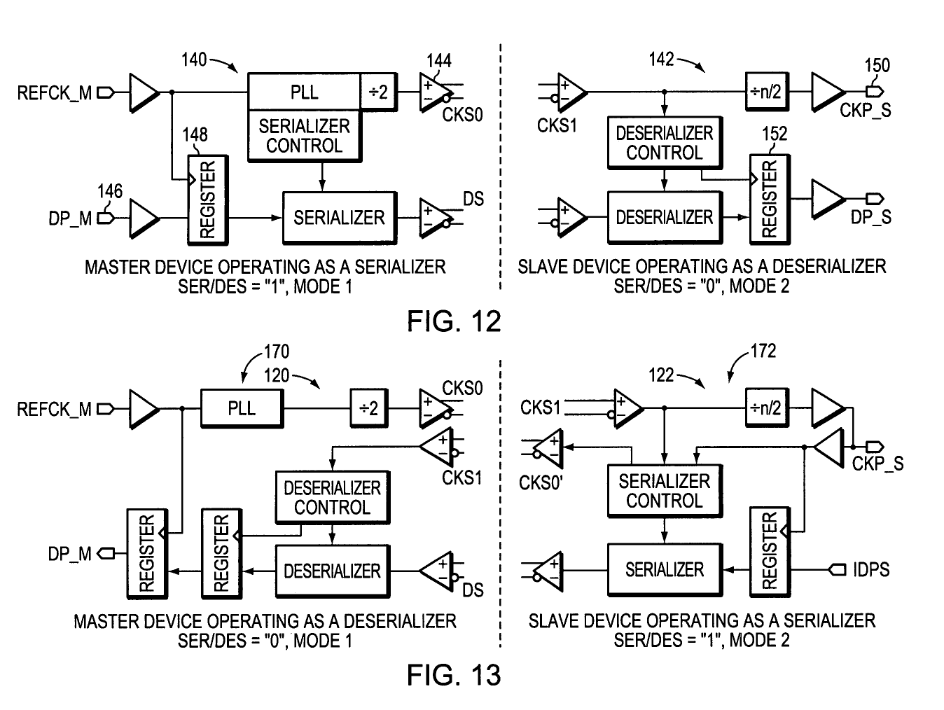

FIGS. 12, 13, 14 and 15 show typical applications of the device illustrating a master/slave operation of two devices as shown in FIG. 5.

In FIG. 12 illustrates a typical serializer/deserializer pair operating as a master/slave with unidirectional data transfers. One device 140 (80 in FIG. 5) is arranged in mode #1 with SER/DES signal set high, the device 140 acting as a serializer. Item 140 acts as the master and is that portion of the device (80 in FIG. 5) primarily operating in this mode. Item 142 is the salve operating as a deserializer receiver of the data from 140. Device 142 is arranged in mode #2 with SER/DES signal set low. REFCK_M is a word clock input to the PLL that generates a bit clock 144 with an embedded word boundary. The bit clock is received by 142 via the CKS1 port as shown. Item 140 receives parallel data 146 from a processor via DP_M port that is loaded into the register 148. That data is serialized and sent out synchronously with the bit clock CKSO via the DS line. The CKSO and the DS are arranged so that each edge of the CKSO is used to load data at the receiver 142.

The slave 142 accepts the CKS1 and generates a word clock CK_P 150. The deserialized DS data stream is loaded into the register 152 and made available on the DP_S port together with the word clock CK_P so that the receiver processor can retrieve the sent data.

FIG. 13 illustrates a master/slave operation where the clock is generated at the master but data flows from the slave to the master. Device 170 is arranged as the master but a deserializer. Device 170 delivers a bit clock CKSO via the PLL and a divider, but with no word boundary. The master receives a bit clock CKS1 from the slave, but the slave has introduced the missing clock pulse word boundary in the clock CKSO′ via the serializer control. Device 170 receives the serial data, parallelizes it, and presents the parallel data to the processor bus DP_M with the REFCK_M. The slave 172 serializes parallel data stored in the register 174 by the CKP_S.

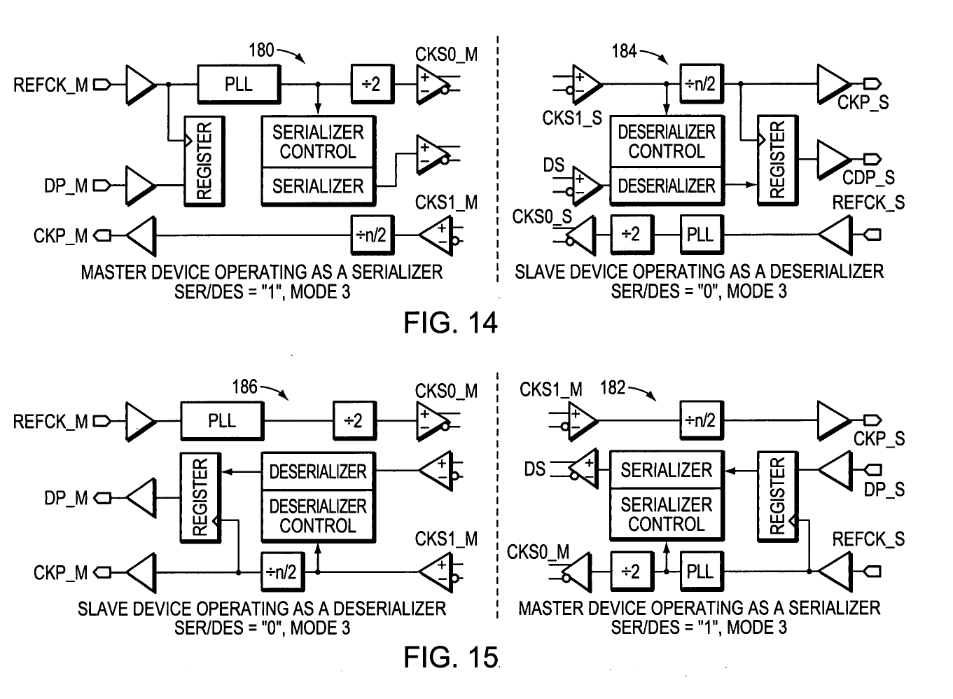

FIGS. 14 and 15 illustrate bidirectional data with PLL's running on both the master and slave device. The clocks running on either side of the serial transmission line are completely independent form each other. In each case, the master 180 in FIG. 14 and 182 in FIG. 15 are placed into mode #3 and each accepts the REFCK and generates a bit clock with an embedded word boundary. Parallel data is received, as described above, and sent synchronously with the bit clocks to the slave devices. In this application, the master accepts from the slave a bit clock with an embedded word boundary and generates a word clock CKP_M. The slave devices 184 and 186 operate as deserializers and accept the bit clock with the embedded word boundaries. The slaves generate the word clock CKP_S(M) and deserialize the data stream using the CKS1 clocks. Parallel data is written onto the DP_S port with the CKPS(M) clock. The slave also generates a free running bit clock based on the REFCK signals and transmits this bit clock to the master.

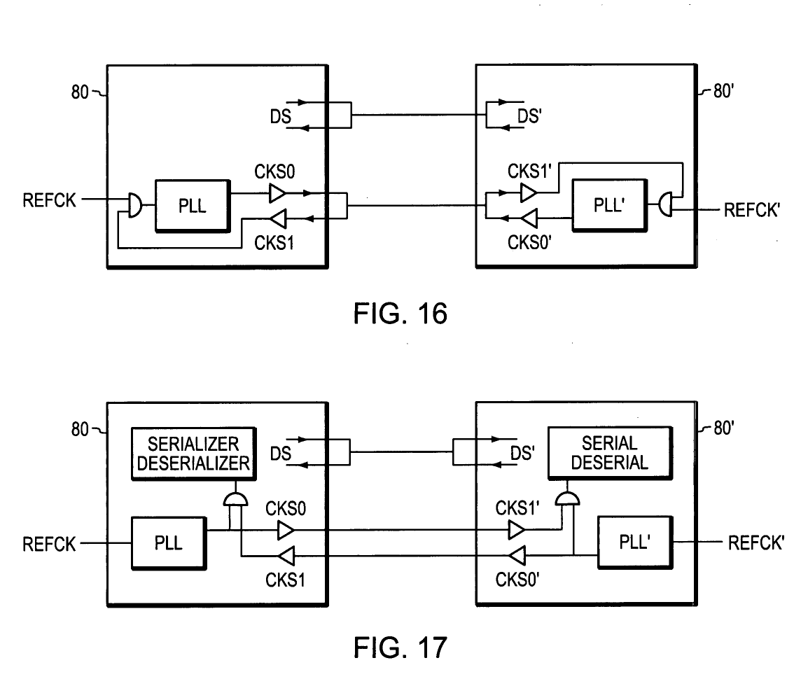

FIG. 16 shows an arrangement where there is a single data line and a single clock line between two devices 80 and 80′ each similar to that in FIG. 5. Here there is bidirectional data transfer where both data and clocks must be turned around to implement the bidirectional data transfers. The data transfers are half duplex and the modes and control of the items 80 and 80′ must be arranged to accommodate the data reversal. The PLL's must be locked before data can be transferred. Control of 80 and 80′ via the mode and clocks, as shown in FIG. 6, can be implemented as is known by system designers in this art field. For some applications this embodiment may be inappropriate principally due to the PLL turn around time that may take hundreds or thousands of REFCK cycles.

As mentioned above, control of turning around the data and clock lines may involve protocols and additional control or status lines between a sender (serializer) and a receiver (deserializer) that may also include a master aware of conditions or status at both ends of the data and clock lines. Also, in the case of episodic data transfers, the PLL's remain locked by feeding them word or reference clock signals. The bit clock on the transmission lines may remain cycling but without any word boundary included. Alternatively, the bit clock may remain in a low where the protocol requires a word boundary to be a bit clock high together with a data line transition so that no word boundary can be detected. Logical combinations may be used as practitioners in the art will be aware. In situations where no data has been transferred in some time, when the bit clock is always being sent, the sending system will begin a data transfer by sending, for example, eight bits of data followed by the word boundary. The receiver will receive the serial data not knowing if it has received data or not, if no word boundary is detected the eight bits of data are deemed to be not useful. In this case, the next bit is shifted into the receiver shift register and the earliest bit is shifted out and lost. This continues until a word boundary is detected at which time the receiver stores the prior eight bits as it is now deemed to constitutes a word. Again, practitioners in the art will understand and be able to institute other techniques that are well known in the art.

FIG. 17 is similar to FIG. 16 except that there are two separate clock lines between device 80 and 80.′ This set up dispenses with any PLL turn around time and so can be used in applications that cannot use the system of FIG. 16. Both 80 and 80′ are arranged for acceptance of parallel data from their respective processors and both are arranged to provide parallel data to those processors, as described earlier. In this implementation when either 80 or 80′ are acting as a deserializer, the PLL in the deserializer need not be used. The transferred bit clock is used to directly load the deserializer as shown in FIG. 13.

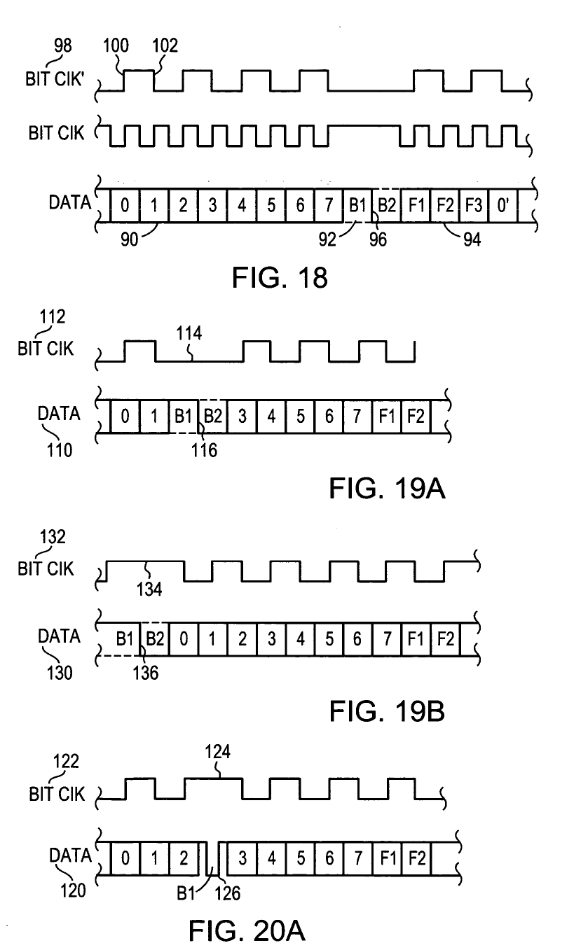

FIG. 18 shows a bit clock scheme with word data bits 90, boundary bits 92, and filler bits 94. In this case a different number of filler bits may be sent between different words. Also, shown is an embodiment where the data is latched on the rising edge only of the bit clock. The bit clock, in such a case as seem from the drawing is running at is twice the data clock frequency. Eight word data bits, 0-7, are stable during the rising edge of the bit clock as sent or as received. In this case, the word boundary bits B1 and B2 are shown with a data bit edge 96 occurring while the bit clock is high. This is the word boundary as described before. Note that the edge 96 may be a rising edge, and also, the edge may be rising on one word boundary but falling on the next or another word boundary. However, in this case, there are filler bits F1, F2, and F3 that occur prior to the next data word bit 0.′ The boundary bits are serially clocked out by a second clock, synchronous with the bit clock, except the second clock has edges suitable to shift out or select (say via a multiplexer) the two boundary bits. This second clock must be present in the other embodiments, since, as shown, the bit clock has no edges during the boundary bit times. In one embodiment, there is a logic level transition between the last data bit and the first of the two boundary bits. So if the last data bit is a logic 1, the first boundary bit will be a logic 0 and the next boundary bit a logic 1. Correspondingly, if the last data bit is a logic 0, the boundary bits, in order, will be logic 1, 0.

Another embodiment shown in FIG. 18 as BIT CLK′ 98 provides for latching the data bits on either a rising 100 or a falling 102 bit clock edge and thereby not to have a double frequency data clock. Logic implementation to accomplish this is known in the art. In this case the BIT CLK′ is at a constant low 104 during the word boundary. The bit clock at the word boundary can be either high or low, and the polarity of the bit clock may be high for one word and low for another within the same data word stream.

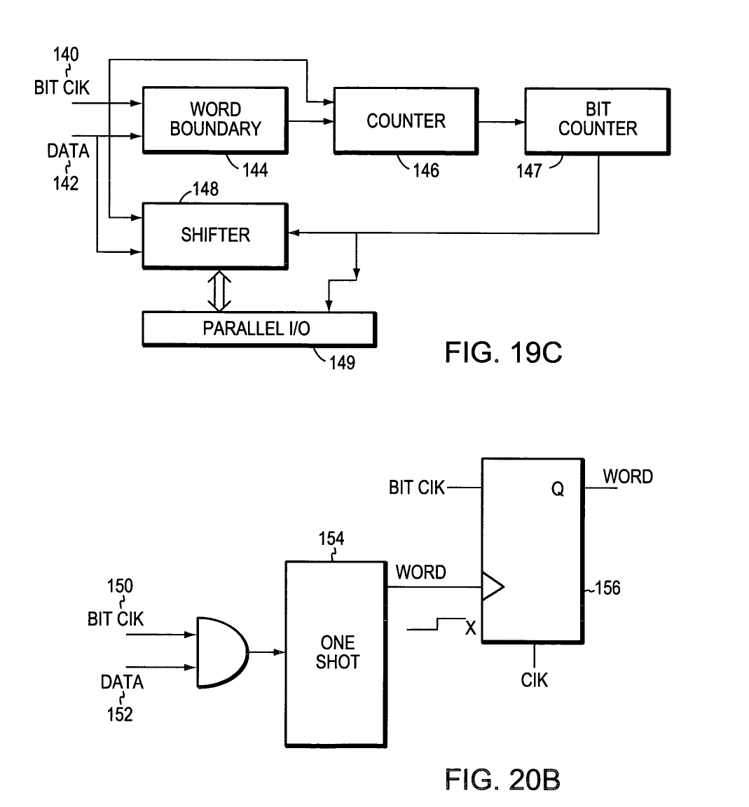

FIG. 19A shows another preferred embodiment of the invention. In this case the word boundary bits B1 and B2 can appear within the data bit stream 110 defining one data word. Here the word boundary bits are between the second and the third data bits. The receiver knows where the boundary bits will be placed and stores the previous received data bits up to where the boundary bits might appear. In FIG. 19A, the receiver at least always stores the first three bits, and if the next two define a word boundary, then the first three and the next five are retained at the receiver to constitute an eight bit word. The determination of the word boundary is, as described above, where the bit clock 112 is constant 114 during two boundary bit times and the boundary bit transition 116 during the constant bit clock defines a word boundary. FIG. 19B shows the data bit stream 130 and the bit clock 132 with the word boundary bits B1 and B2 at the beginning of the data word. Here the constant value bit clock during the boundary bit transition 136 defines the word boundary as discussed before.

FIG. 19C shows one implementation of circuitry that will detect the word boundary at the beginning of a word. The bit clock 140 and data 142 are fed into circuitry 144 that detects the combination indicating a word boundary. When so determined, a counter 146 counts the number of bit clocks that equal a data word. The data is clocked into a shifter 148 until the correct number of data bits have been loaded. The bit counter 149 holds the word now in the shifter 148 and informs a computing system that it may read the data word from the parallel I/O port 149. When the boundary bits are place at the beginning of a data word, there, by definition, will always be filler bits preceding the boundary bits. Here, as above, there will be a forced logic transition between the last filler bit and the fist boundary bit. So, as above, if the last filler bit is a logic 1, the boundary bits in order will be logic 0, 1; and if the last filler bit is a 0, the boundary bits, in order, will be logic 1, 0.

FIG. 20A shows an embodiment where only one boundary bit is used. In this case there is a missing bit clock edge 124 transition during the boundary bit time B1 between data bit 2 and data bit 3. Here the sending system during the single bit word boundary causes a double frequency to appear during that boundary bit time 126. Please note that although the pulse 126 is negative going, a positive going pulse may be used. Again as with the above described embodiment, the bit clock being sent out defines the bit times for the receiving system. Another corresponding clock is used to actually output the bits, usually from a shift register, but also from a multiplexer design.

FIG. 20B shows one simple approach to detecting the double data bit during a high bit clock. In this embodiment, bits are determined on each edge of the bit clock. In this case a word boundary is the B1 of FIG. 20A during a high bit clock 122. An AND condition of a high bit clock and a false data signal 152 produce a trigger on the leading is edge of the false data signal going high to the one shot 154. This one shot outputs a pulse that is set to last until the end of the bit time. If the bit clock is still high then the d-type flop 156 is set and WORD is true. This indicates that a word boundary has been received. During regular data time when data and bit clock combined to trigger the one shot, the bit clock will be low at the end of the data bit time and the flop 156 will not be set. Of course other designs where the bit clock is a constant low and where the data double frequency is a low with a high pulse, opposites of the signals shown in FIG. 20A, are within the skills of practitioners in the art. Also, designs where the bit clock is a double frequency as discussed above are known to those skilled in the art.

It should be understood that above-described embodiments are being presented herein as examples and that many variations and alternatives thereof are possible. Accordingly, the present invention should be viewed broadly as being defined only as set forth in the hereinafter appended claims.

1. A method for finding the boundary between words in a stream of data bits, each data bit defining a bit cycle, the method comprising the steps of:
defining a high and a low logic level;
determining the sequence of bits defining a word;
selecting a data signal defining a word boundary;
adding the word boundary with the bits defining the word;
sending out in serial form the word data bits with the added word boundary;
sending out in parallel with the data bits, a bit clock synchronized with the data bits;
causing the bit clock to maintain a constant logic level during the sending of the word boundary; and
determining the word boundary by sensing the word boundary while the bit clock maintains a constant logic level.

2. The method of claim 1 wherein the step of selecting the boundary comprises the step of creating logic level transitions at a double bit cycle frequency during a bit cycle, the double bit cycle during a bit cycle defining the word boundary.

3. The method of claim 1 wherein the step of determining a word boundary comprises the step of:
selecting two added boundary data bits, the data bits having the same bit cycle as the data bits, the boundary data bits selected so that there is a logic level transition at the s beginning of the first boundary bit and at the junction of the two added boundary data bits.

4. The method of claim 1 wherein the clock logic level remains high during a word boundary.

5. The method of claim 1 wherein the clock logic level remains low during a word boundary.

6. The method of claim 3 wherein the logic level transition at the junction of the two boundary bits is from low to high.

7. The method of claim 3 wherein the logic level transition at the junction of the two boundary bits is from high to low.

8. The method of claim 1 further comprising the steps of placing filler bits before and after the data word and word boundary.

9. The method of claim 1 wherein the word boundary is placed within the word data bits.

10. The method of claim 1 wherein the word boundary is placed before the word data bits.

11. The method of claim 1 wherein the word boundary is placed after the word data bits.

12. The method of claim 3 further comprising the steps of:
loading a parallel data word into a shift register;
defining the word boundary as bits sharing the same bit cycle as the word data bits;
loading the word boundary bits into the shift register;
shifting out the word data bits and the word boundary bits; and
loading the next parallel data word and word boundary bits into the shift register.

13. The method of claim 1 further comprising the steps of:
defining the word boundary as bits sharing the same bit cycle as the word data bits;
receiving the serial word data bits and the word boundary bits;
receiving the synchronous bit clock;
shifting the received word data bits and the word boundary bits, bit by bit, into a shift register using the received synchronous bit clock;
detecting when a data word has been shifted into the shift register, and in response indicating the receipt of the word to a computing system; and
reading the word by the computing system.

14. Apparatus for finding the boundary between words in a stream of data bits, each data bit defining a bit cycle, the apparatus comprising:
means for defining a high and a low logic level;
means for determining the sequence of bits defining a word;
means for selecting a data signal defining a word boundary;
means for adding the word boundary with the bits defining the word;
means for sending out in serial form the word data bits with the added word boundary;
means for sending out in parallel with the data bits, a bit clock synchronized with the data bits;
means for causing the bit clock to maintain a constant logic level during the sending of the word boundary; and
means for determining the word boundary by sensing the word boundary while the bit clock maintains a constant logic level.

15. The apparatus of claim 14 wherein the means for selecting the data signal defining a word boundary comprises means for creating logic level transitions at a double bit cycle frequency during a bit cycle, the double bit cycle during a bit cycle defining the word boundary.

16. The apparatus of claim 14 wherein the means for determining a word boundary comprises:
means for selecting two added boundary data bits having the same bit cycle as the data bits, the boundary data bits selected so that there is a logic level transition at the junction of the two added boundary data bits.

17. The apparatus of claim 14 wherein the clock logic level remains high during a word boundary.

18. The apparatus of claim 14 wherein the clock logic level remains low during a word boundary.

19. The apparatus of claim 14 wherein the logic level transition at the junction of the two boundary bits is from low to high.

20. The apparatus of claim 14 wherein the logic level transition at the junction of the two boundary bits is from high to low.

21. The apparatus of claim 14 further comprising means for placing filler bits before and after the data word and word boundary.

22. The apparatus of claim 14 wherein the word boundary is placed within the word data bits.

23. The apparatus of claim 14 wherein the word boundary is placed before the word data bits.

24. The apparatus of claim 14 wherein the word boundary is placed after the word data bits.

25. The apparatus of claim 17 further comprising:
means for loading a parallel data word into a shift register;
means for defining the word boundary as bits sharing the same bit cycle as the word data bits;
means for loading the word boundary bits into the shift register;
means for shifting out the word data bits and the word boundary bits; and
means for loading the next parallel data word and word boundary bits into the shift register.

26. The apparatus of claim 14 further comprising:
means for defining the word boundary as bits sharing the same bit cycle as the word data bits;
means for receiving the serial word data bits and the word boundary bits;
means for receiving the synchronous bit clock;
means for shifting the received word data bits and the word boundary bits, bit by bit, into a shift register using the received synchronous bit clock;
means for detecting when a data word has been shifted into the shift register, and in response;
means for indicating the receipt of the word to a computing system; and
means for reading the word by the computing system.
